(19) United States
(12) Patent Application Publication
(10) Pub. No.: US 2006/0224336 A1
(43) Pub. Date: Oct. 5, 2006

(54) System and method for transmitting power system data over a wide area network

(75) Inventors: Charles E. Petras, Pullman, WA (US); James C. Anderson, Pullman, WA (US); Armando Guzman-Casillas, Pullman, WA (US); Ping Jiang, Pullman, WA (US); Kenneth J. Fodero II, Pullman, WA (US)

Correspondence Address: COOK, ALEX, MCFARRON, MANZO, CUMMINGS & MEHLER LTD, SUITE 2850, 200 WEST ADAMS STREET, CHICAGO, IL, 60606, US

(73) Assignee: Charles E. Petras

(21) Appl. No.: 11/399,285

(22) Filed: Apr. 5, 2006

Related U.S. Application Data
(60) Provisional application No. 60/668,252, filed on Apr. 5, 2005.

(51) Int. Cl. G01R 21/00

(52) U.S. Cl. 702/62

(57) ABSTRACT

Provided is a system for transmitting synchronized phasors over a wide area network. The system generally includes a plurality of phasor measurement units (PMUs). Each of the PMUs are associated with a secured portion of a power system and measure power system data from the secured portion of the power system associated therewith. The power system data is associated with a time-element. A power system data concentrator is further provided in communication with the phasor measurement units such that it aggregates and time-correlates the power system data. A server is further provided in communication with the power system data concentrator. The server includes a program for transferring the aggregated time-correlated power system data from the secured portion of the power system to a non-secure network.

### RELATED APPLICATION

This application claims the benefit of U.S. Provisional Application No. 60/668,252, filed Apr. 5, 2005.

### BACKGROUND OF THE INVENTION

The present invention concerns the monitoring and protection of electrical power systems. More particularly, the present invention concerns a system and method for transmitting power system data, including but not limited to synchronized phasors, over a wide area network (WAN) over non-secure (public) networks.

Generally, power system control or protective devices are used for protecting, monitoring, controlling, metering and/or automating electric power systems and associated transmission lines. These power system control or protective devices may include protective relays, remote terminal units (RTUs), programmable logic controllers (PLCs), bay controllers, supervisory controlled and data acquisition (SCADA) systems, general computer systems, meters, and any other comparable devices used for protecting, monitoring, controlling, metering and/or automating electric power systems and their associated transmission lines. Some of these power system control or protective devices are further adapted to measure and/or derive synchronized phasor measurements, including but not limited to voltage/current synchronized phasor measurements. Synchronized phasor measurements are generally defined in the IEEE Standard C37.118-2006 and are otherwise referred to as synchronized phasors or synchrophasors.

Devices which measure and/or derive phasors are referred to as phasor measurement units (PMUs). PMUs may further be adapted to measure or derive synchronized phasors. PMU may further be adapted to measure and/or derive other power system values, including but not limited to frequency, voltage magnitude and angle, current magnitude and angle, change in frequency over time, digital values, analog scalar quantities and values derived from power system quantities.

One known approach for measuring synchronized phasors involves using a protective relay. U.S. Pat. No. 6,662,124, assigned to Schweitzer Engineering Laboratories, describes a protective relay for electric power systems for system-wide control and analysis and for protection. This patent is incorporated by reference herein and made a part hereof. The protective relay generally includes an acquisition circuit for obtaining voltage values and/or current values from a power line. A first sampling circuit therein samples the voltage and/or current values at selected intervals of time. A first calculation system uses the resulting samples to perform selected power system-wide control and analysis determinations. A frequency estimating circuit for determining the power system frequency, wherein a second sampling circuit resamples the sampled voltage and/or current values at a rate, which is related to the power system frequency. A second calculation system using the resampled voltage and current values performs selected protection functions for the portion of the power line associated with the protective relay.

U.S. Pat. No. 6,662,124 describes yet another protective relay for electric power systems using synchronized phasors for system-wide control and analysis and for power line protection. This second embodiment protective relay includes voltage and current acquisition circuits for obtaining voltage and current values from a power line. A sampling circuit is further provided for sampling the voltage and current values at selected intervals of time, wherein the sampling is based on an absolute time value reference. A first calculation system using the sampled signals performs selected power system-wide protection, control and analysis determinations and produces synchronized voltage and current phasor values from the acquired voltage and current values. The synchronized voltage and current values are substantially independent of system frequency for protection and control functions. A second calculation system is further provided being responsive to synchronized phasor values from the protective relay and from another relay which is remote from the protective relay on the same power line. Accordingly, U.S. Pat. No. 6,662,124 describes an example of a PMU being a protective relay.

U.S. Pat. No. 6,845,333, assigned to Schweitzer Engineering Laboratories, describes a protective relay for electric power systems for system-wide control and analysis and for protection. This patent is incorporated by reference herein and made a part hereof. The protective relay generally includes an acquisition circuit for obtaining voltage values and current values; from an electric power system. A sampling circuit is further provided for sampling the voltage or current values at selected intervals of time, wherein the sampling is based on an absolute time reference. A communication system is also provided for transmitting messages containing synchronized phasor values from the protective relay to a host device.

U.S. Pat. No. 6,845,333 describes yet another protective relay using synchronized phasors for protection of electric power systems. The second embodiment protective relay includes an acquisition circuit for obtaining voltage values and current values from the power system. A sampling circuit is further provided for sampling the voltage or current values at selected intervals of time, wherein the sampling is based on an absolute time reference. A calculation system is also provided using the sampled signals to produce synchronized voltage or current phasor values. The synchronized voltage or current phasor values are further used to perform selected protection functions for the power system, wherein the synchronized voltage and current phasor values being acquired independent of power system frequency.

U.S. Pat. No. 6,845,333 describes yet another protective relay using synchronized phasors for protection of electric power systems. This third embodiment protective relay includes an acquisition circuit for obtaining voltage values and/or current values from the power system. A sampling circuit is further provided for sampling the voltage or current values at selected intervals of time, wherein the sampling is based on an absolute time reference. A calculation system is also provided using the sampled signals to produce synchronized voltage or current phasor values and then using the synchronized voltage or current phasor values to perform selected protection functions for the power system, wherein the synchronized voltage and current phasor values are acquired independent of power system frequency. The relay further includes a receiving circuit for receiving voltage or current values from another relay which is remote from the protective relay and wherein the calculation system is responsive to the voltage or current values from the protective relay and from another relay to perform selected protection functions for the power system involving the protective relay and another relay.

In this third embodiment of the U.S. Pat. No. 6,845,333 patent, synchronized phasor measurement data from a device is described to be reported in two different ways, unsolicited binary messages at specific time intervals and solicited ASCII messages at specific times. For example, two devices (intelligent electronic devices, such as protective relays) communicate with a host computer over conventional communication channels, using a conventional CRC (cyclical redundancy check) error detection method. Unsolicited binary messages from the IEDs to the host computer typically includes the IED address that is used by the host computer to determine the data source, the sample number of the data, the data acquisition time stamp with the absolute time reference, the power system estimated frequency, the phase and positive sequence voltages and currents from the power line, an indication of correct time synchronization, a confirmation that the data packet is ok, followed by general purpose bits, and lastly, an error detection code.

With solicited messages, the devices respond to a command from the host computer relative to a phasor measurement by reporting synchronized phasor measurements of meter data (magnitude and angle for the three phase currents and voltages) in the power system at specific times. Accordingly, U.S. Pat. No. 6,845,333 describes an example of a PMU being a protective relay.

Although the examples above and the embodiments described herein refer to protective relays, it is contemplated that the present invention may also be associated with any device which measures and/or derives synchronized phasors. For example, in addition to protective relays, remote terminal units (RTUs), programmable logic counters (PLCs), bay controllers, supervisory controlled and data acquisition (SCADA) systems, general computer systems, meters, intelligent electronic devices (IEDs) and any other device used for measuring synchronized phasors may be considered PMUs.

As an indicator of the state of an electric power system, synchronized phasors must be communicated, time-correlated across the system, and compared with other synchronized phasors in order to be valuable. More specifically, a comparison of synchronized phasors provides information regarding power angles across power lines, power transfer, system stability margins, and possible system isolation.

In viewing the landscape of power grids, North America includes five different synchronous networks as shown in FIG. 1, including Eastern Interconnection, Western Interconnection, ERCOT (Texas), Mexico, and Quebec. Every connected generator in each of the power grids is synchronously tied to every other in the network. Nevertheless, within a network, generators that are synchronously tied together are generally not in phase as relative angles between generators change with load flows across the system. Therefore, it is preferable that the phase angles relative to each of the networks and within each network be displayed and communicated.

In an example of system isolation (e.g., islanding), one system within a grid may become out-of-phase with other systems within the same grid. When islanding occurs, a system becomes out of synch from a nominal frequency or out of phase. When the islanded system is later reconnected without being synchronous to the phase and frequency of the grid, severe damage or complete destruction can occur to the switchgears and generators. Therefore, it is an objective of this invention to provide a system and method for monitoring system isolation or islanding within a grid.

PMUs have been traditionally interconnected together through fiber optic cable or other physical connections. These interconnections often prove to be very costly and involve multiple high cost lines. Accordingly, it is further desired that synchronized phasors be sent across a wide-area network. Because the power system is a secured network, it is also desired to transmit synchronized phasors from the secured portion of the power system to a non-secure network. It is yet another objective of the present invention to transmit and display other power system values such as frequency, voltage magnitude and angle, current magnitude and angle, change in frequency over time, digital values, and analog scalar quantities. In this manner, an end user may easily access the power system data.

It is also desirable to align and correlate the synchronized phasors from different sites (e.g., within or between power grids). It is yet another object of the present invention to display and update synchronized phasors and other power system values in real time to show any relationship between different sites.

These and other desired benefits of the preferred embodiments, including combinations of features thereof, of the invention will become apparent from the following description. It will be understood, however, that a process or arrangement could still appropriate the claimed invention without accomplishing each and every one of these desired benefits, including those gleaned from the following description. The appended claims, not these desired benefits, define the subject matter of the invention. Any and all benefits are derived from the multiple embodiments of the invention, not necessarily the invention in general.

### SUMMARY OF INVENTION

According to an aspect of the invention, disclosed is a system for transmitting synchronized phasors over a wide area network. The system generally includes a plurality of phasor measurement units (PMUs). Each of the PMUs are associated with a secured portion of a power system and measure power system data from the secured portion of the power system associated therewith. The power system data is associated with a time element and may be selected from a group consisting of phasors, synchronized phasors, frequency, voltage magnitude and angle, current magnitude and angle, change in frequency over time, digital values, analog scalar quantities and values derived from power system quantities.

A power system data concentrator is further provided in communication with the phasor measurement units such that it aggregates and time-correlates the power system data. A server is further provided in communication with the power system data concentrator. The server includes a program for transferring the aggregated time-correlated power system data from the secured portion of the power system to a non-secure network.

In accordance with another aspect of the invention, each of the secured portions of the power system are located in different power system grids. Accordingly, each of the phasor measurement units are associated with different power system grids.

In accordance with another aspect of the invention, the power system data is associated with a time element using a high-accuracy clock communicating with each of the phasor measurement units.

In accordance with another aspect of the invention, the non-secure network is the internet.

In accordance with another aspect of the invention, the system further includes a firewall or a virtual private network for providing security between the secured portion of the power system and the non-secure network.

In accordance with another aspect of the invention, the program for transferring the aggregated time-correlated power system data from the secured portion of the power system to the user accessible network further comprises a buffer.

In accordance with another aspect of the invention, the server includes a program for graphically depicting the power system data. Furthermore, it is further provided that the secured portions of the power system may be graphically depicted on a map and the power system data may be graphically displayed therewith.

According to an aspect of the invention, a method for transmitting synchronized phasors over a wide area network is provided. The method generally includes the steps of measuring power system data for a secured portion of a power system; time-correlating the power system data; aggregating the time-correlated power system data; and transferring the aggregated time-correlated power system data from the secured portion of the power system to a user accessible network.

### BRIEF DESCRIPTION OF THE DRAWINGS

FIG. 1 illustrates a power grid synchronous network of North America.

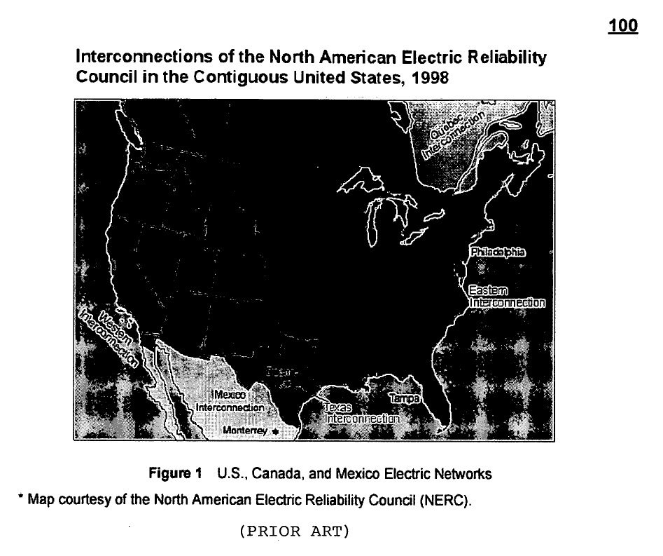

FIG. 2 is a one-line schematic diagram of an electric power system in a typical metropolitan area.

FIG. 3 illustrates a phasor measurement unit (PMU) coupled with a high-accuracy clock using a communications link.

FIG. 4 illustrates an example of the data format that may be used in the phasor measurement unit of FIG. 3.

FIG. 5 depicts a configuration of a phasor measurement unit as a protective relay.

FIG. 6 illustrates an embodiment of a system and method for transmitting power system data from a secured network to a non-secure network.

FIG. 7 illustrates an embodiment of a PDC buffer storing synchronized system data to be polled by a web server.

FIG. 8 illustrates another embodiment of a system and method for transmitting power system data from a secured network to a non-secure network.

FIG. 9 illustrates yet another embodiment of a system and method for transmitting power system data from a secured network to a non-secure network.

FIG. 10 illustrates a graphical display of power system data of United States in accordance to an embodiment of the present invention.

FIG. 11 illustrates a global visualization in accordance to an embodiment of the present invention.

### DETAILED DESCRIPTION OF THE EMBODIMENTS

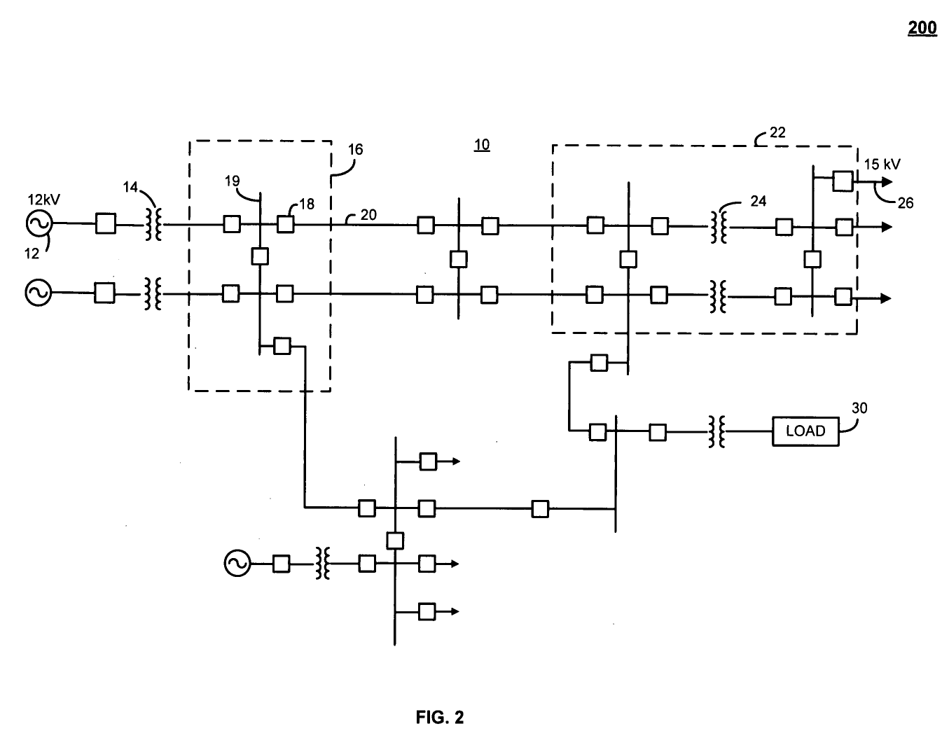

According to an aspect of the invention, FIG. 2 is a one-line schematic diagram of a power system 10 that may be utilized in a typical metropolitan area. As illustrated in FIG. 2, the power system 10 includes, among other things, a generator 12 configured to generate three-phase sinusoidal waveforms at, for example, 12 kV, a step-up transformer 14 configured to increase the 12 kV sinusoidal waveforms to a higher voltage such as 345 kV, and a first substation 16 including a number of circuit breakers 18 and transmission lines 20 interconnected via a first substation bus 19. The first substation 16 provides the higher voltage sinusoidal waveforms to a number of long distance transmission lines such as a transmission line 20. At the end of the long distance transmission line 20, a second substation 22 includes a step-down transformer 24 to transform the higher voltage sinusoidal waveforms to a lower voltage (e.g., 15 kV) suitable for distribution via a distribution line 26 to various end users and loads.

As previously mentioned, the power system 10 includes protective devices and procedures to protect the power system elements from abnormal conditions. Some of the protective devices and procedures act to isolate corresponding protected elements (e.g., the transmission line 20) of the power system 10 upon detection of short circuit or fault. Other types of protective devices used in the power system 10 provide protection from thermal damage, mechanical damage, voltage sags and transient instability.

The protective devices and procedures utilize a variety of logic schemes to determine whether a fault or other problem exists in the power system 10. For example, the protective device may be in the form of a protective relay which utilizes a current differential comparison to determine whether a fault exists in the protected element. Other types of protective relays compare the magnitudes of calculated phasors representative of the three-phase sinusoidal waveforms to determine whether a fault exists. Frequency sensing techniques and harmonic content detection is also incorporated in protective relays to detect fault conditions. Similarly, thermal model schemes are utilized by protective relays to determine whether a thermal problem exists in the protected element.

For example, protection for the generator 12 may be provided by a generator differential protective relay (e.g., ANSI 87G [ref. ANSI/IEEE Std C37.2]), protection for the transformer 14 may be provided by a transformer overcurrent relay or a transformer differential protective relay (e.g., ANSI 87T) and protection for the circuit breaker 16 may be provided by a breaker failure relay. Similarly, protection for the transmission line 20 may be provided by a phase and ground distance relay or a line current differential relay (e.g., ANSI 87L), and protection of the distribution line 26 may be provided by a directional overcurrent and reclosing relay. Many protective logic schemes are possible.

In almost all cases however, step-down current and voltage transformers are used to connect the protective relays to their corresponding higher power protected elements. The resulting lower secondary currents and voltages can be readily monitored and/or measured by the protective relays to determine corresponding phasors that are used in the various overcurrent, voltage, directional, distance, differential, and frequency protective relay logic schemes. As an indicator of the state of an electric power system, synchronized phasors must be communicated, time correlated across the system, and compared with other synchronized phasors in order to be valuable. More specifically, a comparison of synchronized phasors provides information regarding power angles across power lines, power transfer, system stability margins, and possible system isolation. Phasors may be obtained using any phasor measurement unit (PMU). For example, in this particular, the protective relay may obtain phasors from a portion of the power system and, therefore, be considered a PMU.

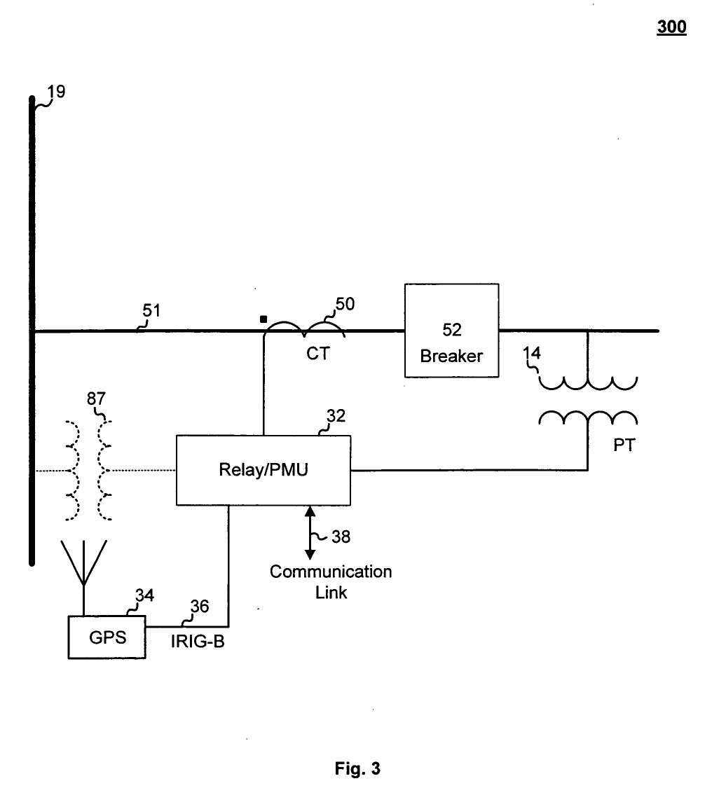

FIG. 3 illustrates a general system 300 diagram of a phasor measurement unit (PMU) 32, which may be in the form of a protective relay or any other such device, coupled with a high-accuracy clock (e.g., GPS clock) 34 using a communications link 38. Using the high-accuracy clock, the phasors measured or derived by the PMU 32 may further be associated with a time component. An example of a high-accuracy clock may include a clock which is synchronized to a global positioning system (GPS) or a Cesium clock. The high-accuracy clock submits a signal for synchronizing phasors based on Universal Time Coordinated (UTC). In order for an accurate phasor measurement, the synchronized signal is preferably accurate within about 500 ns of UTC. It is important to note that the phasors may be associated with a time component using any other time measurement means. Suitable forms of time communications links 36 include IRIG-B, IEC 61588 Ethernet link or other such communications links.

More specifically, the PMU 32 attains instantaneous current samples from line 51 through current transformer 50 and voltage samples from power bus 19 through power transformer 14. This system 300 may be within the power system 200 of FIG. 2. The PMU 32 processes these samples and thereupon derives phasors from such. In order to synchronize the samples, the phasors are marked with a certain time associated with the high-accuracy clock 34. In order to communicate such data to external devices such as other PMUs, protective devices, computers, etc., the PMU 32 generally further includes a binary output with another communications link 38 to such external devices.

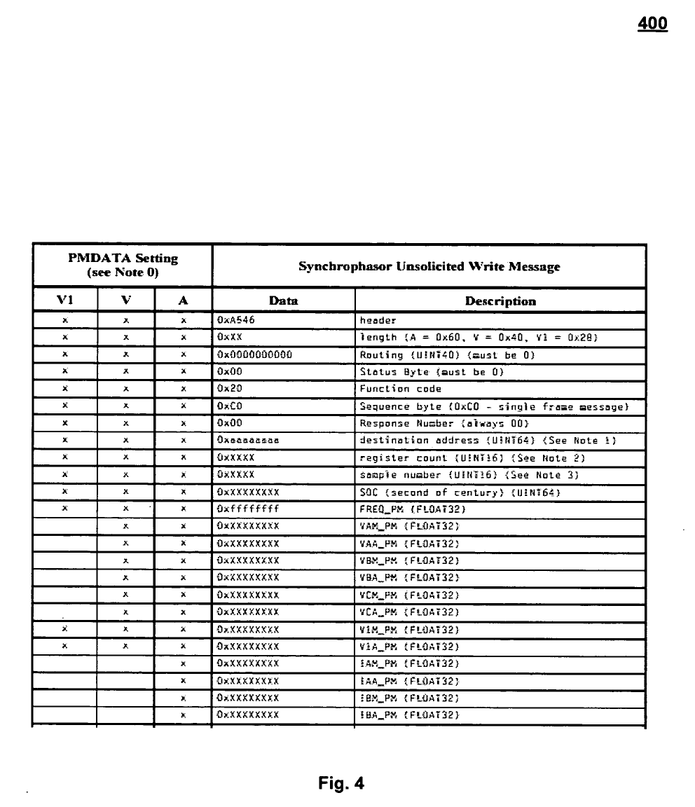

A setting in each phasor measurement unit in the form of PMDATA, for example, may define the analog quantities the unit will send in the message. The message may have the format as presented in FIG. 4. The message may further conform to an IEEE data format or any other suitable format.

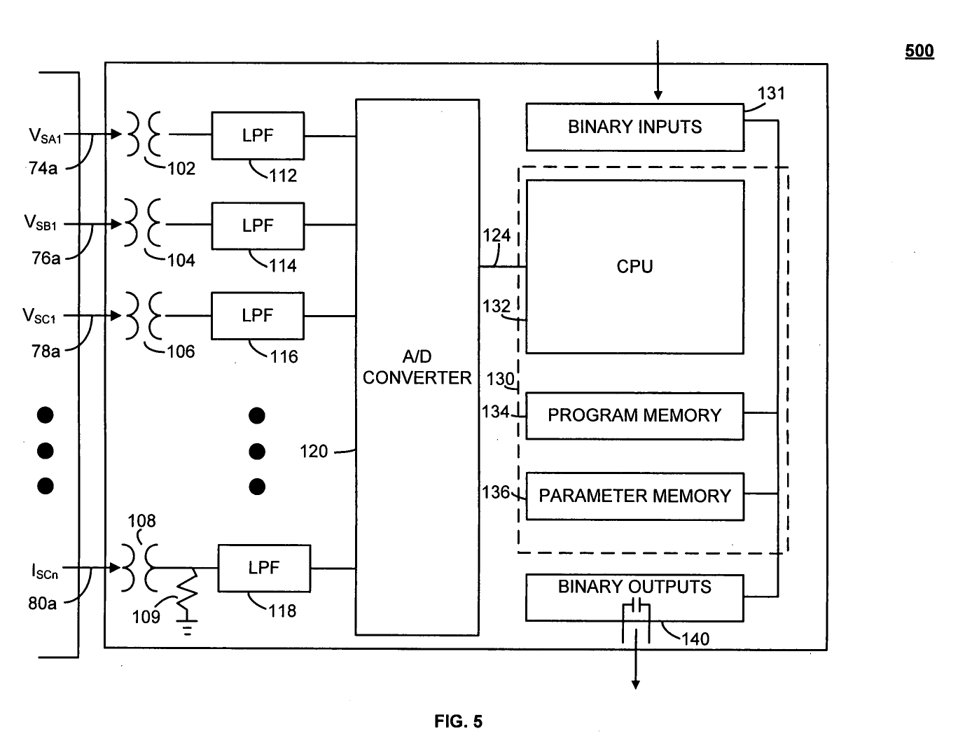

In one example, as shown in FIG. 5, the PMU 32 may be a protective relay 500 adapted to transmit synchronized phasors. FIG. 5 is a block diagram of an exemplary configuration of a protective relay 500 wherein the secondary voltage and current waveforms 74a, 76a, 78a to 80a are illustrated as V_{SA1}, V_{SB1}, V_{SC1} and I_{SCn}, Although only secondary voltage and current waveforms 74a, 76a, 78a to 80a are shown in FIG. 5, it should be noted that all secondary voltage and current waveforms (i.e., CT signals) of the current transformers are included.

Referring to FIG. 5, during operation, the secondary voltage waveforms 74a, 76a, 78a and current waveform 80a received by the protective relay 500 are further transformed into corresponding voltage and current waveforms via respective voltage and current transformers 102, 104, 106, to 108 and resistors 109, and filtered via respective analog low pass filters 112, 114, 116 to 118. An analog-to-digital (A/D) converter 120 then multiplexes, samples and digitizes the filtered secondary current waveforms to form corresponding digitized current sample streams (e.g., 1011001010001111).

The corresponding digitized voltage and current sample streams are received by a microcontroller 130, where they are digitally filtered via, for example, a pair of Cosine filters to eliminate DC and unwanted frequency components. From these samples, microcontroller 130 may also be adapted to measure and calculate phasors. Also, microcontroller 130 may be adapted to receive signals via binary inputs 131 from other external devices such as a high-accuracy clock, protective devices or external computers using a suitable communications link. For example, the binary inputs 131 may include, among other things, phasors from other protective devices or computers as described in U.S. Pat. Nos. 6,845,333 and 6,662,124. Binary input may further include data streams as those described in U.S. Pat. No. 5,793,750 for “System for Communicating Output Function Status Indications Between Two or More Power System Protective Relays” and U.S. Pat. No. 6,947,269 for “Relay-to-Relay Direct Communication System in an Electric Power System,” both of which are incorporated herein in their entirety and for all purposes. Using a high-accuracy clock (e.g., the GPS clock 34 of FIG. 3) as a binary input, microcontroller may thereupon synchronize phasors.

In this relay, the microcontroller 130 further includes a microprocessor, or CPU 132, a program memory 134, and parameter memory 136. The relay is adapted to measure phasor values and implement over current, voltage, directional, distance, differential, and frequency protective logic schemes. The logic elements associated therewith are generally programmed into the program memory 134 or permanently hard coded into parameter memory 136. The microprocessor 132 is coupled to the program memory 134 and the parameter memory 136 so that it may access the logic elements associated therewith in order to perform various protective functions and phasors.

The microcontroller 130 thereupon produces binary outputs 140 which may signal protective function or which may provide power system data. In one embodiment, the microcontroller produces a synchronized phasor measurement which may be transmitted over a communications link (e.g., the communications link 38 of FIG. 3) to other protective devices or to a WAN via Ethernet data transmission as will be described in detail below.

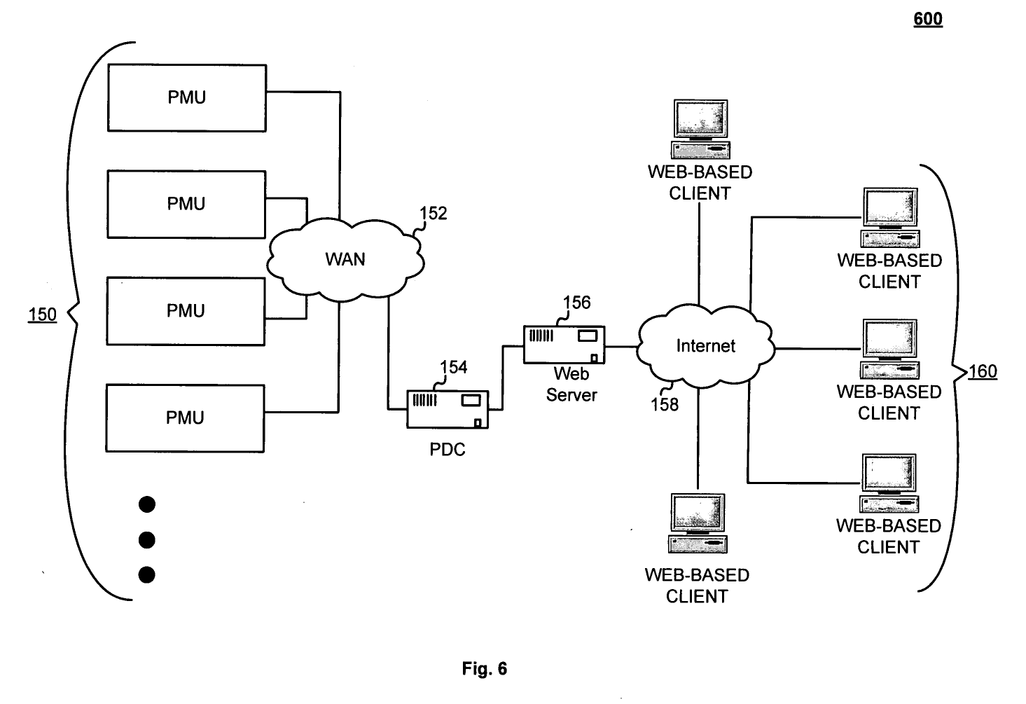

In another embodiment as illustrated in FIG. 6, multiple PMUs 150 are connected for communications over a wide area network (WAN) 152. Each of the PMUs 150 are associated with a secured portion of a power system. Each of the PMUs 150 are adapted to measure or derive synchronized phasors. PMU may further be adapted to measure and/or derive other power system values, including but not limited to frequency, voltage magnitude and angle, current magnitude and angle, change in frequency over time, digital values, analog scalar quantities and values derived from power system quantities. Accordingly, power system data as defined herein may include both synchronized phasors and also the other power system values as defined above. Each of the PMUs 150 may be on the same or even different power system grids. The power system data measured or derived by the PMUs 150 may further be associated with a time-element as discussed above (e.g., using a high-accuracy clock associated therewith).

For communication over the WAN 152, serial data is converted for Ethernet data transmission via an Ethernet transceiver for serial-only PMUs. Alternatively, for Ethernet native PMUs, such devices are directly connected to the Ethernet. Ethernet data is then sent via Transmission Control Protocol/Internet Protocol (TCP/IP), User Datagram Protocol (UDP), or other similar means over the WAN 152, which may be transmitted via several different communications media.

A device for aggregating and correlating the power system data, otherwise known as a power system data concentrator 154, may be connected to the WAN 152. The power system data concentrator 154 may be adapted to aggregate among other power system data, phasor data, and be therefore referred to as a phasor data concentrator (PDC). The PDC may further be adapted to time-correlate the power system data. The PMUs 150, WAN 152 and the power system data concentrator 154 are associated with a secured portion of the power system.

The power system data is to be transferred from the secured portion of the power system to a non-secure portion of the power system. Accordingly, a server 154 may be provided including a program for transferring the aggregated time-correlated power system data from the secured portion of the power system to a non-secure network. The server 154 may be in the form of a web server. In order to maintain security between the secured portion of the power system and the non-secure network, the server may include security communications means (e.g., a Virtual Private Network (VPN) connection, firewall or other similar security means). For example, a virtual private network may be established between the PMUs 150 and the power system data concentrator 154 to create an encrypted tunnel therebetween.

The web server 156 provides the collected power system data over the non secure network (e.g., Internet 158) or other communications means to a plurality of web-based clients 160.

In yet another embodiment, the PDC 154 may be a software-based program residing in a dedicated server. Alternatively, the PDC 154 may be in another form or may reside in a computer. The PDC 154 may further be adapted to connect the PMUs 150 using TCP/IP connections over respective Ethernet connections. In one embodiment, the PDC 154 is adapted to receive power system data, which is recorded over a select period of time. Accordingly, power system data may be recorded in a buffer or otherwise be stored in a database. The stored power system data may be used to provide historical data or trend information.

As discussed above, the PDC 154 is adapted to receive power system data. For example, the power system data may include an embedded time stamp. The time stamp provides an absolute reference to which all data can be compared to provide relative reference between different data for indication of phase angle shift, error in time alignment, and error in phase angle. The time stamp may be in the form of a second of century (SOC), wherein a unique message label, message number or fractional second for further subdividing the SOC is implemented. For example, at data reception, the PDC 154 may correlate each message using the SOC and message number in a selected buffering system.

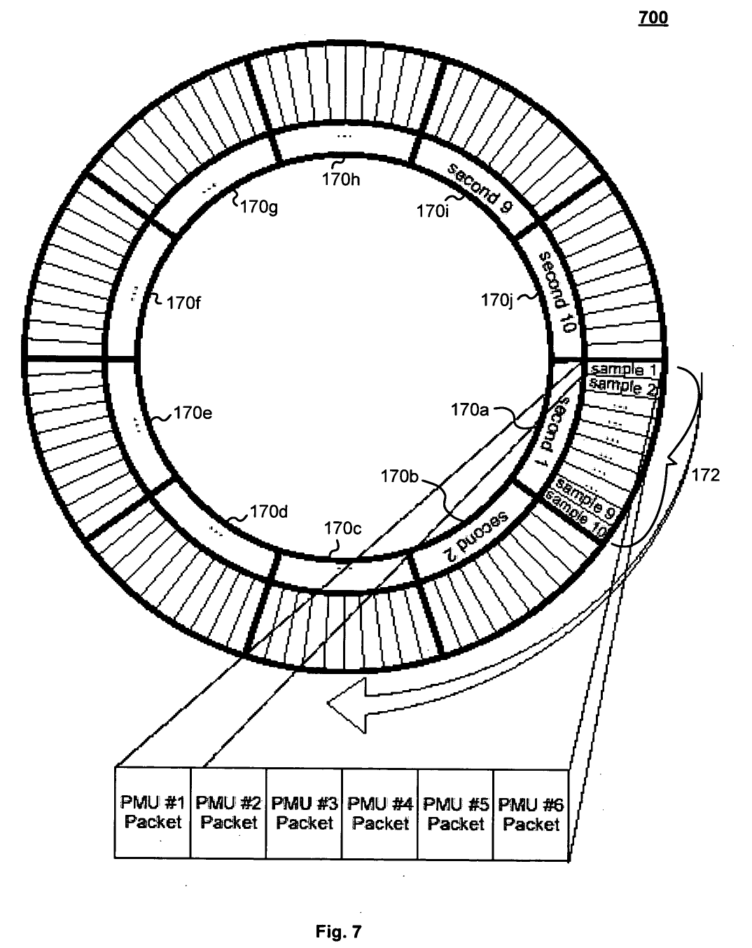

In yet another embodiment, the program for transferring the aggregated time-correlated power system data from the secured portion of the power system to a non-secure network may include a buffer. In one example, a ten-second buffer may be provided as illustrated in FIG. 7. The buffer 700 comprises of 10 slots 170a-j, each storing one second of data from all of the PMUs 150. Although a ten second buffer is described in this embodiment, other longer or shorter buffers may further be implemented. The slots 170a-j are further subdivided into various sample allocations 172. In this case, although sample allocations 172 for each slot are shown in this embodiment, other sized sample allocations may further be implemented. In this way, power system data may be recorded in this buffer.

In yet another embodiment, the program for transferring the aggregated time-correlated power system data from the secured portion of the power system to a non-secure network may be in the form of a script. In one example, a script is implemented using the buffer 700 of FIG. 7. The script moves the power system data from the PDC to a web server. The web server runs the script that periodically polls the PDC using a UDP or any other comparable protocol. The script may further be adapted to ensure and enhance the completeness of data transmitted from the PDC to the web server. For example, the script analyzes the packets sent by the concentrator and chooses the oldest data set within the buffer period that includes responses from the most PMUs. Accordingly, the script or other comparable program implemented provides for a real-time streaming data while providing minimal latency. In this embodiment, a one-second refresh rate is implemented although other suitable rates may further be used which minimizes internet communications traffic.

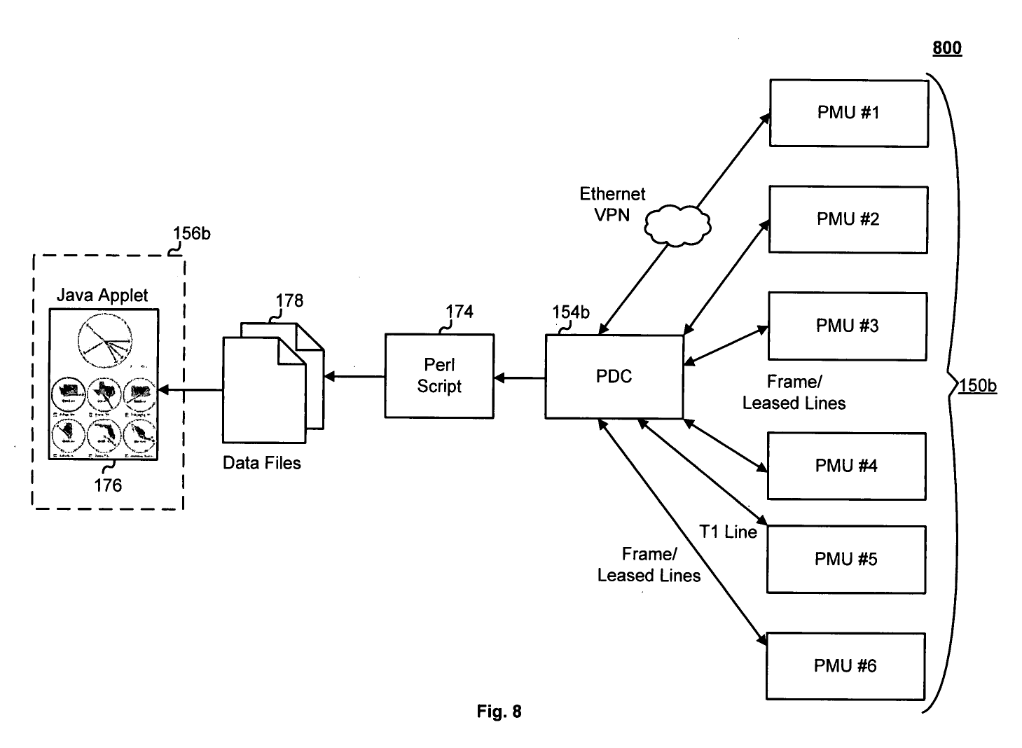

In yet another embodiment as illustrated in FIG. 8, the program may be written in the Perl script 174 programming language for moving the power system data from a PDC 154b to a web server 156b. The web server 156b runs Perl script 174 that periodically polls the PDC 154b using a UDP or any other comparable protocol. The Perl script 174 causes data files 178 to be written to the web server 176. The web-based clients may access the power system data from multiple PMUs 150b via an applet 176, which is downloaded along with a respective web page and runs from within the client's web browser 156b. An applet is a program that is generally written in the Java programming language and embedded within a web page; other languages and methods are also available. The applet 176 is generally downloaded along with the web page by the web-based client and runs from within the web-based client's web browser. For example, the applet 176 may, among other things, collect data from the web server 156b, calculate phase angles, and render graphical representations of power system data.

More particularly, when a web-based client accesses the web page, the Java applet 176 is loaded from the web server 156b. When the Java applet 176 is launched in a web browser, it reads the data file 178 that contains the list of PMUs 150b connected to the PDC 154b. The Java applet 176 then would periodically read the data file 178 that contains the PMU data to be displayed. For example, one applet may use data to configure the display to show phasor plots for each PMU 150b connected to the PDC 154b. Another applet may start a ten-minute rolling display of frequency. Other web page programming languages other than Java may further be implemented such as HTML or XML.

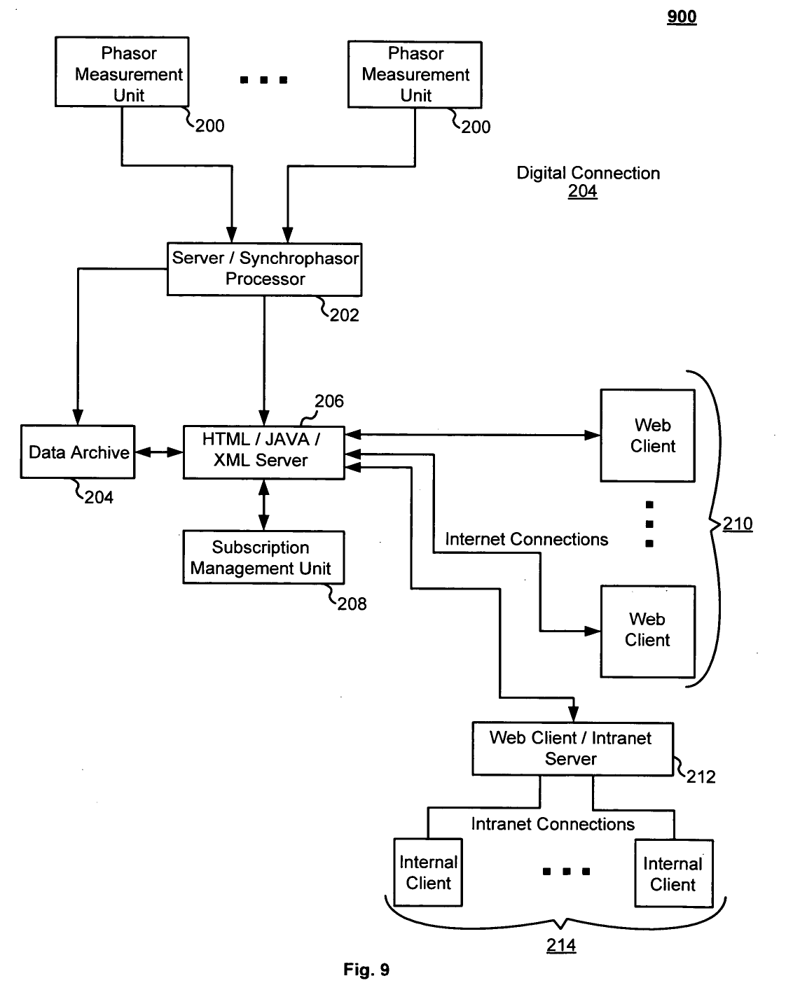

FIG. 9 illustrates a system in accordance with yet another embodiment of the present invention. This system includes a plurality of PMUs 200. These PMUs 200 may be coupled with a high-accuracy clock (e.g., GPS clock) using a communications link (e.g., IRIG-B or IEC 61588 Ethernet link). The PMUs are connected to a server/Synchrophasor Processor 202 using for example TCP/IP connections over respective Ethernet or direct serial connections 204. The server/Synchrophasor Processor 202 receives power system data with embedded time stamp such as described in detail above with respect to the PDC. At data reception, the server/Synchrophasor Processor 202 may further be adapted to time correlate the data and data number in a selected buffering system.

A database in the form of a data archive 204 is coupled to the server/Synchrophasor Processor 202 for receiving power system data and recording such over a select period of time. The server/Synchrophasor Processor 202 and database 204 may be connected to a web server 206 which may be adapted to implement JAVA, HTML, XML, or other web-based language. Perl script or other such program may be implemented for moving the power system data from the server/Synchrophasor Processor 202 to a web server 206 or the data archive 204 to the web server 206. The data transfer program may further be adapted to ensure that enhance the completeness of data transmitted from the server/Synchrophasor Processor 202 to the web server 206 or the data archive 204 to the web server 206.

The web server 206 may be connected to a subscription management unit 208 and web clients 210 via conventional Internet connections. The web clients 210 connected to the web server 206 may access the phasors via an applet. Each of the web clients 210 may further an intranet server 212 whereupon multiple internal clients 214 are established.

A subscription management unit may 208 be used to limit access to each web client 210 or internal client 214. For example, the subscription management unit 208 may be used to password protect and maintain a payment system, whereupon a web client 210 or internal client 214 would be required to provide password and/or payment to access such data from the web server 210. For example, a subscription service may be implemented whereupon power system data is stored in the web server 210. A web client 214 may access such data to view power system data, including synchronized phasors, among systems or PMUs within the same electric power system or among different electric power grids.

For example, upon receipt of a request from a customer (e.g., either a web client or internal client) using a web browser, the web server 206 provides access to an online subscription management tool hosted by the web server 206. Utilizing various web pages transmitted via the customer's browser, the customer submits a user name and password. The user name and password is submitted to the web server which verifies the customer's account balance by comparing such with data stored in the server. In this way, the web server 206 may limit access to only customers with subscriptions thereto.

In accordance with the various aspects of this invention, a display is provided to the web client wherein real-time power system data, including synchronized phasors, may be visualized. The system may also be adapted such that it displays the status information wherein the system is offline or does not have a synchronized time source.

In accordance with another aspect of the invention, the server may include a program for graphically depicting the power system data. For example, the applet may include graphical depiction of such data. In yet another embodiment, portions of the power system and the power system data associated therewith may be graphically depicted on a map. In one example, the user may select either synchronized frequency measurements or synchronized voltage magnitudes for various locations within an electric power system or among different electric power grids.

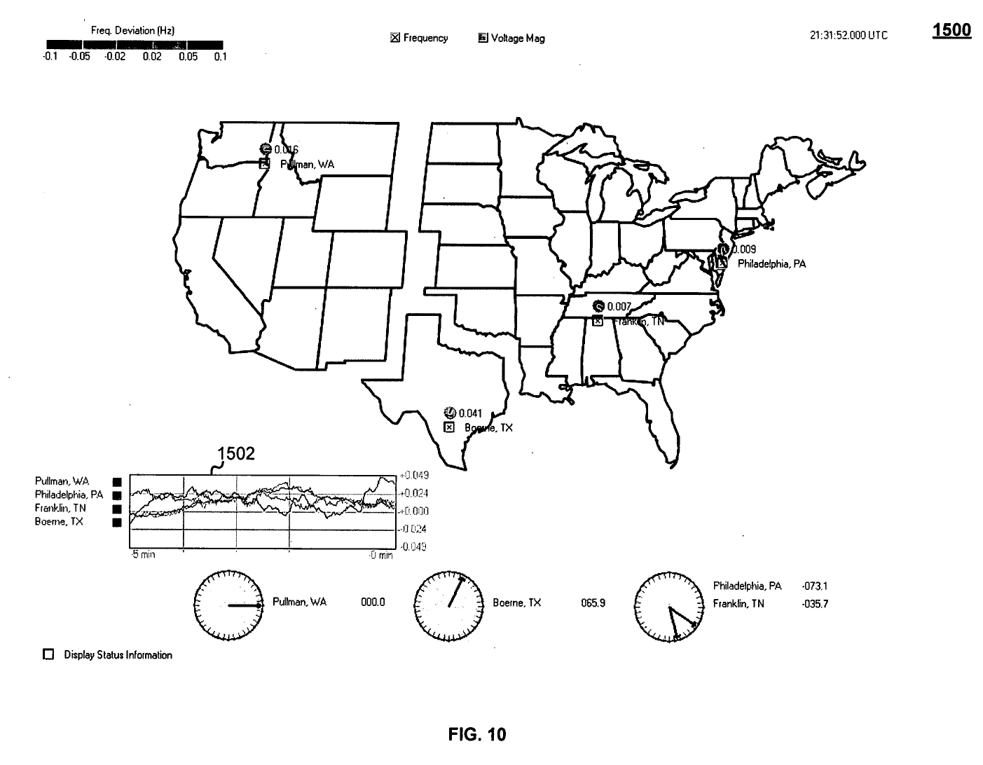

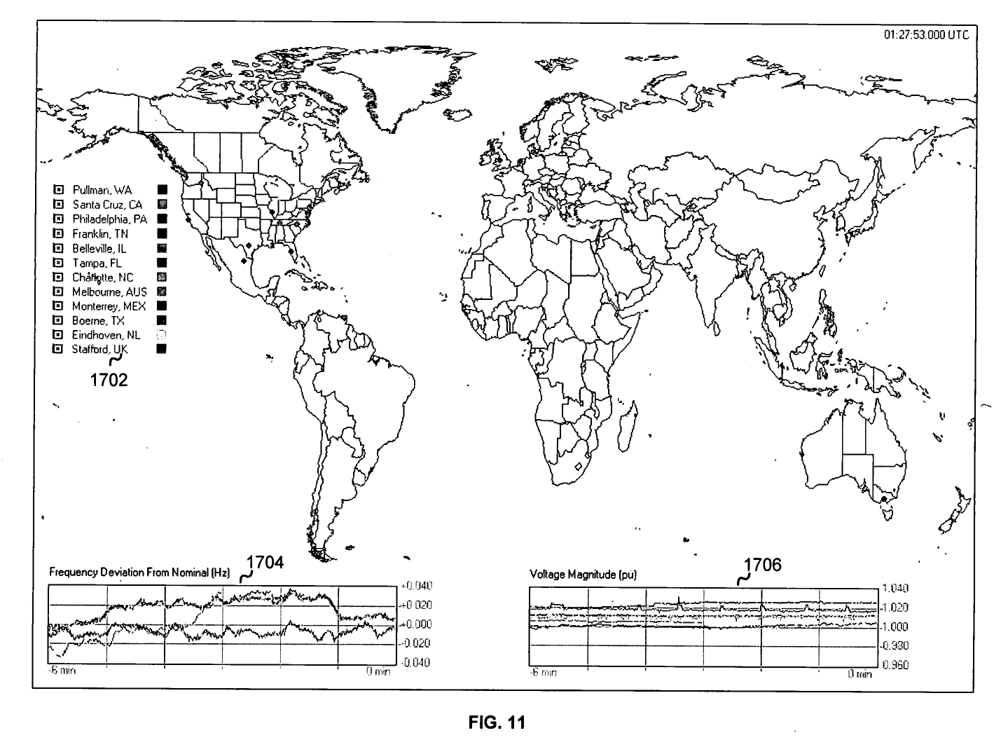

For example, FIG. 10 illustrates a graphical display 1500 of power system data, i.e., frequency deviation 1502 over a period of five minutes of United States on a web page. FIG. 11 illustrates a global visualization of power system data. For example, the left side of the graphical display depicts the validity of data states from a list of 12 sites 1702 from around the world. Each PMU corresponds to a solid dot in the world map. The dots may be depicted in several different colors, each represent a state. For example, gray may depict that the PMU is offline; yellow may depict the time of PMU is not synchronized to a high-accuracy clock; red may depict the data that is displayed and transmitted from the PMU is not valid; and green may depict valid message and time is good, etc.

In yet another embodiment, the graphical display may further include a depiction for other power system data. This may be depicted in text or graphical format. For example, the power system data may appear at the PMU location on the map or otherwise in a listing format. Also, the graphical display may include a graph 1704 for displaying frequency deviation from nominal value for the select period of time (e.g., in this case, for the last 6 minutes). Another graph 1706 may also be provided for displaying voltage magnitude per unit for a select period of time (e.g., in this case, for the last 6 minutes).

In yet another embodiment, the graphical display may depict when a PMU is selected from the graphical screen (e.g, through another color or flashing dot associated therewith).

While this invention has been described with reference to certain illustrative aspects, it will be understood that this description shall not be construed in a limiting sense. Rather, various changes and modifications can be made to the illustrative embodiments without departing from the true spirit, central characteristics and scope of the invention, including those combinations of features that are individually disclosed or claimed herein. Furthermore, it will be appreciated that any such changes and modifications will be recognized by those skilled in the art as an equivalent to one or more elements of the following claims, and shall be covered by such claims to the fullest extent permitted by law.

1. A system for transmitting synchronized phasors over a wide area network, comprising:
a plurality of phasor measurement units, each of said phasor measurement units associated with a secured portion of a power system and each of said phasor measurement units measuring power system data from the secured portion of the power system associated therewith, said power system data having a time element associated therewith,
power system data concentrator in communication with the phasor measurement units, said power system data concentrator aggregating and time-correlating the power system data, and
a server in communication with the power system data concentrator, said server including a program for transferring the aggregated time-correlated power system data from the secured portion of the power system to an non-secure network.

2. The system of claim 1 wherein each of the secured portions of the power system are located in a same power system grid, thereby each of the phasor measurement units being associated with the same power system grid.

3. The system of claim 1 wherein each of the secured portions of the power system are located in different power system grids, thereby each of the phasor measurement units being associated with different power system grids.

4. The system of claim 1 wherein the power system data is associated with a time element using a high-accuracy clock communicating with each of the phasor measurement units.

5. The system of claim 4 wherein the high-accuracy clock is synchronized to a global positioning system.

6. The system of claim 1 wherein the power system data is selected from a group consisting of phasors, synchronized phasors, frequency, voltage magnitude and angle, current magnitude and angle, change in frequency over time, digital values, analog scalar quantities, values derived from power system quantities, and values derived from power system status.

7. The system of claim 1 wherein the non-secure network is the internet.

8. The system of claim 1 wherein the server further comprises a firewall for providing security between the secured portion of the power system and the non-secure network.

9. The system of claim 1 wherein the server further comprises a virtual private network between the phasor measurement units and the power system data concentrator.

10. The system of claim 1 wherein the server stores historical power system data.

11. The system of claim 10 wherein the historical power system data provides trend power system data.

12. The system of claim 1 wherein the program for transferring the aggregated time-correlated power system data from the secured portion of the power system to the user accessible network further comprises a buffer.

13. The system of claim 1 wherein the program for transferring the aggregated time-correlated power system data from the secured portion of the power system to a user accessible network is a perl script program.

14. The system of claim 1 wherein the server includes a program for graphically depicting the power system data.

15. The system of claim 14 wherein the server includes an applet including the graphical depiction of the power system data.

16. The system of claim 1 wherein the secured portions of the power system are graphically depicted on a map and the power system data is graphically displayed therewith.

17. The system of claim 1 wherein the server includes a java applet for providing real-time depiction of power system data.

18. The system of claim 1 further comprising a database in communication with the power system data concentrator for storing the power system data therein.

19. The system of claim 1 further comprising a subscription management unit in communication with the server.

20. A method for transmitting synchronized phasors over a wide area network, comprising the steps of:
measuring power system data for a secured portion of a power system, said power system data being associated with a time element;
time-correlating the power system data,
aggregating the time-correlated power system data, and
transferring the aggregated time-correlated power system data from the secured portion of the power system to a user accessible network.

21. The method of claim 20 wherein the power system data is selected from a group consisting of phasors, synchronized phasors, frequency, voltage magnitude and angle, current magnitude and angle, change in frequency over time, digital values, analog scalar quantities and values derived from power system quantities.

22. The method of claim 20 wherein the user accessible network is the internet.

23. The method of claim 20 further including securing the communication between the secured portion of the power system and the user accessible network.

24. The method of claim 20 further including buffering the power system data during the transferring of aggregated time-correlated power system data from the secured portion of the power system to the user accessible network further.

25. The method claim 20 further including graphically depicting the power system data.

26. The method claim 25 further including graphically depicting the secured portions of the power system on a map.
